(19) United States
(12) Patent Application Publication
(10) Pub. No.: US 2024/0356487 A1
(43) Pub. Date: Oct. 24, 2024

(54) LOW-TEMPERATURE BIFACIAL PHOTOVOLTAIC MODULE

(71) Applicants: XI'AN THERMAL POWER PRODUCT CERTIFICATION AND TESTING CO., LTD., Shaanxi (CN); XI'AN THERMAL POWER RESEARCH INSTITUTE CO., LTD., Shaanxi (CN)

(72) Inventors: Bo Yang, Shaanxi (CN); Shujuan Wang, Shaanxi (CN); Qiong Wu, Shaanxi (CN); Lei Zhao, Shaanxi (CN); Hang Xi, Shaanxi (CN); Wenji Cheng, Shaanxi (CN); Kai Niu, Shaanxi (CN); Zengbo Liu, Shaanxi (CN); Taijiang Li, Shaanxi (CN)

(21) Appl. No.: 18/251,633

(22) PCT Filed: Dec. 28, 2022
(86) PCT No.: PCT/CN2022/142774

§ 371 Date: May 3, 2023

(30) Foreign Application Priority Data
Aug. 15, 2022 (CN) 202210977007.3

(51) Int. Cl. H02S 40/42; H02S 10/10; H10N 10/10; H10N 19/00

(52) U.S. Cl. CPC H02S 40/42; H02S 10/10; H10N 10/10; H10N 19/00

(57) ABSTRACT

A low-temperature bifacial photovoltaic (PV) module includes a backsheet of PV module. A junction box is provided on one side of the backsheet of PV module, and a glass panel, a solar panel and a thermoelectric module layer are provided successively on the other side of the backsheet of PV module. The thermoelectric module layer includes a plurality of p/n-type semiconductors arranged in an array to achieve direct conversion from thermal energy to electrical energy by utilizing a temperature difference between the p/n-type semiconductors and the PV module.

### CROSS-REFERENCE TO RELATED APPLICATIONS

This application is the U.S. National Stage of PCT/CN2022/142774 filed on Dec. 28, 2022, which claims priority to Chinese Patent Application 202210977007.3 filed on Aug. 15, 2022, the entire content of both are incorporated herein by reference in their entirety.

### FIELD OF THE INVENTION

The present application belongs to the technical field of PV assemblies, and in particular relates to a low-temperature bifacial PV module.

### BACKGROUND OF THE INVENTION

PV power generation is a technology that uses the PV effect of a semiconductor interface to transform optical energy directly into electrical energy, and is widely used in solar power generation. A PV module is affected by the environment during long-term operation and emits heat itself. If the PV module is not cooled down in time, hot spots will be generated, which reduces power generation efficiency of the PV module and affects normal operation of a PV power station.

Most of existing PV module cooling technologies for PV power stations use a fan to blow cold air to a PV panel or add a cooling water device to cool down and dissipate heat from a PV module. However, these methods have no obvious cooling effect, and are labor-consuming, leading to waste of water resources. Therefore, there is an urgent need to develop a more active way to cool down an PV module in order to improve power generation efficiency and service life of a PV power station.

### SUMMARY OF THE INVENTION

A technical problem to be solved by the present application is to provide a low-temperature bifacial PV module for the above-mentioned drawbacks in the prior art. A thermoelectric module layer is added in an PV module manufacturing process, which can increase power generation efficiency of the PV module while reducing the temperature of the PV module, by temperature-difference power generation, to solve the problem of high temperature on the surface and in the interior of the PV module due to the influence of the external environment during use of the existing PV module, which greatly affects an output power.

The present application adopts the following technical solution:

A low-temperature bifacial PV module, comprising a backsheet of PV module, with a junction box being provided on one side of the backsheet of PV module and a thermoelectric module layer being provided on the other side of the backsheet of PV module, a cold end of the thermoelectric module layer being connected to the backsheet of PV module, a hot end of the thermoelectric module layer being connected to one side of the PV module, and a glass panel being provided on the other side of the PV module;

wherein the thermoelectric module layer comprises a plurality of p/n-type semiconductors, the plurality of p/n-type semiconductors being arranged in an array, to achieve direct conversion from thermal energy to electrical energy by utilizing a temperature difference between the p/n-type semiconductors and the PV module.

Specifically, one end of each of the p/n-type semiconductors is connected to the PV module through a base.

Optionally, a corresponding metal connection sheet is provided between each p/n-type semiconductor and the base.

Specifically, the plurality of p/n-type semiconductors are successively connected in series by a busbar to form the thermoelectric module layer, and positive and negative electrodes of the thermoelectric module layer are respectively connected to positive and negative electrodes of the junction box.

Optionally, the p/n-type semiconductors are connected to the backsheet of PV module through metal connection sheets.

Specifically, positive and negative electrodes of the PV module are respectively connected to positive and negative electrodes of the junction box.

Optionally, the PV module includes a plurality of solar cells, the plurality of solar cells being connected in series or in parallel by means of a busbar.

Specifically, each of the p/n-type semiconductors is made of a nano-block system, an organic polymer material system or a carbon material system.

Specifically, a first EVA/POE layer is provided between the PV module and the glass panel, a second EVA/POE layer is provided between the thermoelectric module layer and the PV module, and a third EVA/POE layer is provided between the thermoelectric module layer and the backsheet of PV module.

Specifically, the glass panel, the PV module, the thermoelectric module layer and the backsheet of PV module are encapsulated by an aluminum frame.

Compared with the prior art, the present application has at least the following beneficial effects:

In the low-temperature bifacial PV module of the present application, the thermoelectric module layer generates power by using a temperature difference to achieve direct conversion from thermal energy to electrical energy, while reducing the temperature of the PV module, which can prevent the generation of hot spots, and does not require additional bypass diodes; moreover, compared with a conventional PV module, it improves an open circuit voltage and current of the PV module, thereby increasing the power of the PV module.

Optionally, the ceramic base in the thermoelectric module layer is connected to the solar cells by EVA/POE to form the hot end of the thermoelectric module layer, so the thermoelectric module layer achieves temperature-difference power generation, thereby reducing the temperature of the solar cells to prevent the generation of hot spots. In addition, power generation efficiency of the PV module is further improved due to the lowered temperature of the solar cells.

Optionally, the thermoelectric module layer is formed by the p/n-type semiconductors by means of the corresponding metal connection sheets and the base respectively. The structure is highly vibration-resistant, does not generate noise, has a long life, and is convenient to install. In addition, the base is generally a highly thermally conductive material, which can improve thermoelectric conversion efficiency, and the metal connection sheets are used to control a current.

Optionally, a plurality of p/n-type semiconductors successively form a thermoelectric module layer by means of the base and metal connection sheets together, and thermoelectric module layers are connected in series/parallel by a busbar to form a layer of thermoelectric module layer, positive and negative electrodes of the layer of thermoelectric module layer being respectively connected to positive and negative electrodes of the junction box, thereby achieving thermoelectric conversion.

Optionally, the metal connection sheets in the thermoelectric module layer are connected to the backsheet of PV module by EVA/POE to form the cold end of the thermoelectric module layer, and the hot end and the cold end of the thermoelectric module layer are combined to act together to achieve thermoelectric conversion.

Optionally, positive and negative electrodes of the PV module are respectively connected to positive and negative electrodes of the junction box to output electrical energy.

Optionally, the plurality of solar cells are successively arranged closely in series/parallel by means of a busbar to form a solar panel of the PV module. A single solar cell cannot directly generate power, so the solar cells are arranged in series/parallel to form a solar panel, which as a core element of a PV power generation system, functions to convert solar energy into electrical energy.

Optionally, the p-type and n-type thermoelectric elements composed of a nano-block material, an organic polymer material or a carbon material can achieve thermoelectric conversion, which reduces the influence of temperature on PV cell power generation. In addition, the thermoelectric elements have the advantages of a small size, a light weight, no moving components, no noise, no pollution, etc., which is in line with the concept of green energy.

Optionally, EVA/POE, collectively referred to as a PV adhesive film, has the characteristics of light transmission, strong adhesion and durability, and can adapt to a long-time outdoor working environment. The first EVA/POE layer achieves the combination of the glass panel and the solar cells of the PV module to reduce the influence of the outdoor environment on the solar cells. The second EVA/POE layer achieves the combination of the solar cells and the thermoelectric module layer, which together form the hot end of the thermoelectric module layer to prevent the generation of hot spots. The third EVA/POE layer achieves the combination of the thermoelectric module layer and the backplane, which together form the cold end of the thermoelectric module layer to achieve thermoelectric conversion.

Optionally, the aluminum frame has high strength and corrosion resistance, and can support and protect the entire solar panel and thermoelectric module layer. Furthermore, mounting holes of the PV module are provided in the aluminum frame, which allows the PV module to be connected to a bracket through the aluminum frame to form a PV array.

In summary, by adding the thermoelectric module layer, the present application achieves photoelectric conversion and thermoelectric conversion, and improves the amount of power generated by the PV module. Using a PV module of 540W as an example, the amount of power generated by the PV module of the present application can be increased by 12.3%-14.8%. Furthermore, as the thermoelectric module layer has the advantages of a small size and a light weight, design standards of existing PV power stations are not changed. In addition, the PV module uses a temperature difference to generate power, so hot spots are not generated and diodes are saved, and it can extend the life of the PV module and reduce safety risks of a power station.

Technical solutions of the present application are further described in detail below in conjunction with the accompanying drawings and embodiments.

### BRIEF DESCRIPTION OF THE DRAWINGS

FIG. 1 is a structural diagram of the present application;

FIG. 2 is a structural diagram of a thermoelectric module layer of the present application;

FIG. 3 is a circuit connection diagram of a thermoelectric module layer and solar cells of the present application;

FIG. 4 shows a circuit diagram of a conventional PV module; and

FIG. 5 is an I-V curve comparison diagram of an PV module of the present application and a conventional PV module.

Reference numerals: 1. glass panel; 2. first EVA/POE layer; 3. solar cell; 4. second EVA/POE layer; 5. thermoelectric module layer; 5-1. base; 5-2. p/n-type semiconductor; 5-3. metal connection sheet; 6. third EVA/POE layer; 7, backsheet of PV module; 8, junction box; 9. aluminum frame; 10. busbar; 11. bypass diode.

### DETAILED DESCRIPTION OF THE INVENTION

Technical solutions in embodiments of the present application will be described below clearly and completely in conjunction with the accompanying drawings in the embodiments of the present application. Obviously, the described embodiments are a part of the embodiments of the present application, and not all the embodiments. All other embodiments obtained by those of ordinary skill in the art without creative work, based on the embodiments in the present application, fall into the protection scope of the present application.

In description of the present application, it needs to be appreciated that orientation or position relations denoted by the terms “center”, “longitudinal”, “transverse”, “upper”, “lower”, “front”, “rear”, “left”, “right”, “vertical”, “horizontal”, “top”, “bottom”, “inner”, “outer”, “a side”, “an end, “an edge”, and the like are orientation or position relations illustrated based on the drawings, and are merely for the convenience of describing the present application and simplifying description, instead of indicating or implying the denoted devices or elements must have specific orientations or be constructed and operated in specific orientations, and thus the terms cannot be construed as limiting the present application. In addition, the terms “first”, “second” and the like are used only for descriptive purposes and cannot be construed as indicating or implying relative importance or implicitly indicating the numbers of indicated technical features. Thus, a feature qualified by the term “first”, “second” or the like may explicitly or implicitly include one or more such features. In description of the present application, the term “plurality” means two or more, unless otherwise stated.

In description of the present application, it is to be noted that, unless otherwise expressly specified and defined, the terms “install”, “be connected with”, and “be connected” should be construed in a broad sense. For example, it may indicate fixed connection, or detachable connection, or integrated connected; it may indicate mechanical connection, or electrical connection; it may indicate direct connection, or indirect connection through an intermediate medium, or internal communication between two elements. For those of ordinary skill in the art, specific meanings of the above-mentioned terms in the present application may be construed according to specific circumstances.

It should be understood that when used in the specification, the terms “include” and “comprise” indicate the presence of a described feature, whole, step, operation, element, and/or component, but do not exclude the presence or addition of one or more other features, wholes, steps, operations, elements, components, and/or collections thereof.

It should also be understood that terms used in the specification of the present application are only for the purpose of describing specific embodiments and are not intended to limit the present application. As used in the specification of the present application, the singular forms “a/an”, “one” and “one” are intended to include plural forms, unless the context clearly indicates otherwise.

It should also be further understood that the term “and/or” used in the specification of the present application refers to any combination and all possible combinations of one or more of items listed in connection therewith, and includes such combinations.

Various structural diagram according to embodiments disclosed in the present application are shown in the drawings. These drawings are not drawn to scale, in which some details are enlarged and some details may be omitted, for the purpose of clarity of expression. The shapes of various regions and layers shown in the drawings, and their relative sizes and position relations are only exemplary, and there may be deviations in practice due to manufacturing tolerances or technical limitations, and those skilled in the art may additionally design regions/layers with different shapes, sizes, and relative positions as needed practically.

The present application provides a low-temperature bifacial PV module, which uses a thermoelectric module layer to achieve cooling and efficiency increase. The thermoelectric module layer is mainly high-performance p-type and n-type thermoelectric devices composed of a nano-block system such as Bi₂Te₃, SnSe, Ag₂Se, Cu₂Se, Mg₂Si, Mg₂Sb₃, and Bi₂S₃, an organic polymer material system, and a carbon material system. These thermoelectric materials achieve direct conversion from thermal energy to electrical energy by using a temperature difference by means of the Seebeck effect or the Peltier effect, and solve the problem of reduced output power caused by a maximum power temperature coefficient (typically −0.35%/° C.) of a crystalline silicon PV module.

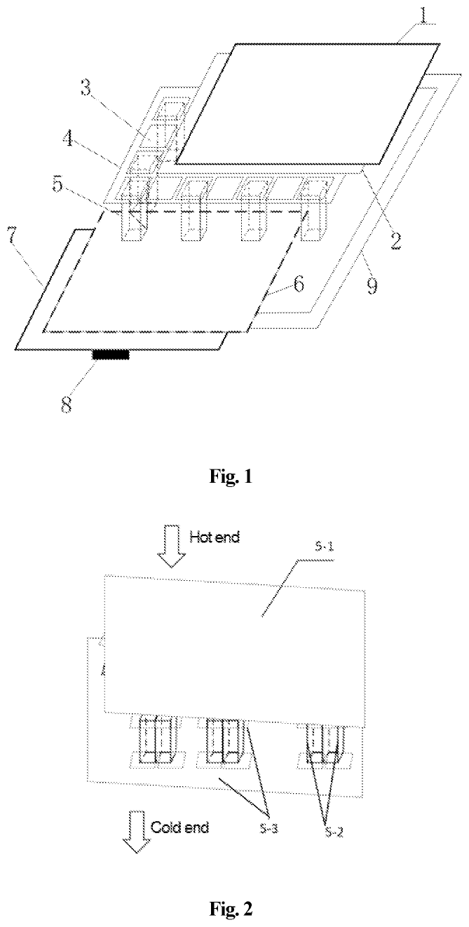

Referring to FIG. 1, a low-temperature bifacial PV module of the present application includes a glass panel 1, a first EVA/POE layer 2, solar cells 3, a second EVA/POE layer 4, a thermoelectric module layer 5, a third EVA/POE layer 6, a backsheet of PV module 7, a junction box 8, and an aluminum frame 9.

The low-temperature bifacial PV module includes, successively from top to bottom, the glass panel 1, the first EVA/POE layer 2, the solar cells 3, the second EVA/POE layer 4, the thermoelectric module layer 5, the third EVA/POE layer 6, the backsheet of PV module 7, and the junction box 8, with the aluminum frame 9 being provided on an outer side of the low-temperature bifacial PV module.

Glass panel 1: covers the top of the solar cells 3 to protect the solar cells 3, has very good light transmittance and high hardness, and can adapt to a large range of day and night temperatures and harsh weather conditions.

First EVA/POE layer 2: connects the glass panel 1 to the solar cells 3 by an EVA/POE film. The EVA/POE film therebetween functions to bond them.

Solar cells 3: the solar cells, as core components of the photovoltaic assembly, are polycrystalline silicon or monocrystalline silicon cells, which convert optical energy into electrical energy by means of the PV effect. The PV module comprises 64 or 72 solar cells 3.

Second EVA/POE layer 4: connects the solar cells 3 to the thermoelectric module layer 5 by EVA/POE. The EVA/POE film therebetween functions to bond them.

Thermoelectric module layer 5: p-type and n-type thermoelectric materials composed of a nano-block system such as Bi₂Te₃, SnSe, Ag₂Se, Cu₂Se, Mg₂Si, Mg₂Sb₃, and Bi₂S₃, an organic polymer material system, and a carbon material system, which achieve temperature-difference power generation by means of the Seebeck effect or the Peltier effect.

Third EVA/POE layer 6: connects the thermoelectric module layer 5 to the backsheet of PV module 7 by EVA/POE. The EVA/POE film therebetween functions to bond them.

Backsheet of PV module 7: the backplate functions to protect the solar cells, and the backplate must be sealed, insulated, waterproof and aging resistant. The material of the backsheet of PV module 7 is TPT, TPE or tempered glass.

Junction box 8: as a current transit station, protects a power generation system of the entire PV module, and automatically disconnects a shorted cell string when there is a short circuit in cells.

Aluminum frame 9: the PV module frame is made of aluminum alloy, which has good strength and corrosion resistance; it can function to support and protect the entire PV module; and mounting holes of the PV module are also provided in the frame, which allows the PV module to be connected to a bracket through the frame.

Referring to FIG. 2, the thermoelectric module layer 5 includes a plurality of p/n-type semiconductors 5-2. The p/n-type semiconductors 5-2 are arranged in an array. An upper end of each p/n-type semiconductor is connected to one side of a base 5-1 through a metal connection sheet 5-3, respectively, the other side of the base 5-1 being connected to a corresponding solar cell 3, respectively, and a lower end of the p/n-type semiconductor is connected to the backsheet of PV module 7 through a metal connection sheet 5-3 via the third EVA/POE layer 6.

The base 5-1 is a protective thermoelectric material, generally made of ceramic or other highly thermally conductive material.

The p/n-type semiconductors 5-2 are p-type and n-type thermoelectric elements composed of a nano-block system such as Bi₂Te₃, SnSe, Ag₂Se, Cu₂Se, Mg₂Si, Mg₂Sb₃, Bi₂S₃, graphene, and carbon nanotubes, an organic polymer material system, or a carbon material system, which achieve temperature-difference power generation by means of the Seebeck effect or the Peltier effect. Two ends of each of the p-type thermoelectric elements and n-type thermoelectric elements are welded to metal connection sheets 5-3, respectively, to improve electrical conductivity.

The metal connection sheets 5-3 are used to connect the p/n-type semiconductors 5-2, to achieve a current conducting effect.

The metal connection sheets 5-3 are made of copper current-conducting sheets, copper solder ribbons or copper-plated metal sheets.

Power lines are welded to the metal connection sheets 5-3, and the power lines are connected to a power supply, thus completing preparation of low-temperature thermoelectric devices.

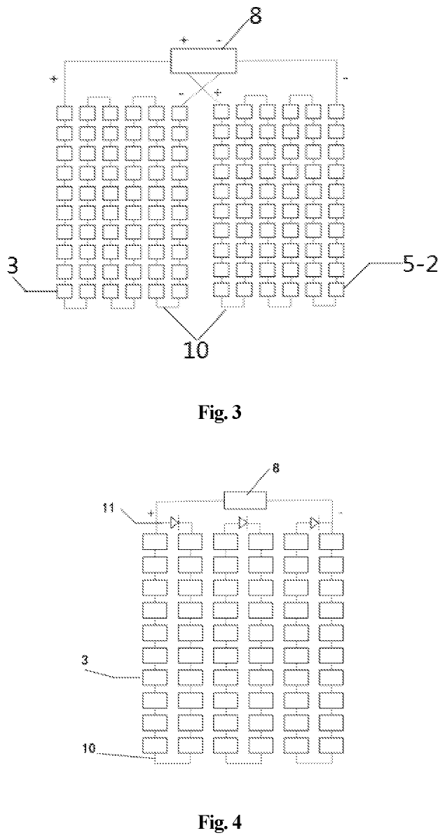

Referring to FIG. 3, circuitry of the PV module of the present application is as follows: a plurality of solar cells 3 are successively connected in series by means of a busbar 10 to form a PV module. A positive electrode of the PV module is connected to a positive electrode of the junction box 8 through a front circuit of the PV module, and a negative electrode of the PV module is connected to a negative electrode of the junction box 8. A plurality of p/n-type semiconductors 5-2 are successively connected in series/parallel by a busbar 10 to form the thermoelectric module layer 5. A positive electrode of the thermoelectric module layer 5 is connected to the positive electrode of the junction box 8, and a negative electrode of the thermoelectric module layer 5 is connected to the negative electrode of the junction box 8 through a back circuit of the PV module.

Referring to FIG. 4, a connecting circuit of a conventional PV module has bypass diodes 11, while bypass diodes are omitted in the PV module proposed in the present application. Furthermore, in the present application, a plurality of solar cells 3 are successively connected in series by a busbar 10 to form a solar panel. A positive electrode of the solar panel passes a front side of the assembly to form a solar cell circuit. On a back side of the assembly is a circuit of the thermoelectric module layer 5. The two circuits are connected in parallel to the junction box 8, which improves an open circuit voltage and current of the assembly. Therefore, both a circuit diagram of the conventional assembly and a circuit diagram of this assembly should show the positive electrode of 8, and a negative electrodes of the solar panel is connected to a negative electrode of the junction box 8. In addition, to prevent the generation of hot spots, a bypass diode 11 is connected in parallel between positive and negative electrode of each string of solar cells.

To make the objects, technical solutions and advantages of embodiments of the present application clearer, a clear and complete description of the technical solutions in the embodiments of the present application will be given below in conjunction with the drawings in the embodiments of the present application. Apparently, the embodiments described are part of, rather than all of, the embodiments of the present application. The PV module of embodiments of the present application generally described and shown in the drawings here can be arranged and designed in a variety of different configurations. Therefore, the following detailed description of embodiments of the present application provided in the drawings is not intended to limit the scope of the present application for which protection is claimed, but merely indicates selected embodiments of the present application. All other embodiments obtained by those of ordinary skill in the art without creative work, based on embodiments in the present application, fall into the protection scope of the present application.

Surface temperature of an PV module of a PV power station in summer is as high as 70° C. to 80° C., with a temperature difference relative to ambient temperature reaching 30° C. to 40° C. A temperature difference between surface temperature of the PV module of the PV power station in winter and ambient temperature is 20° C. to 30° C.

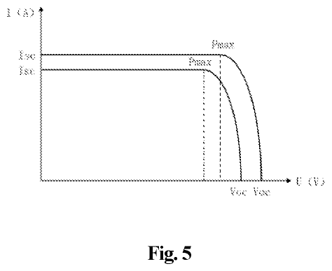

Referring to FIG. 5, an increase of the amount of generated power in the present application is calculated as follows:

$$Δ η = {η}_{1} + {η}_{2}$$

$${η}_{1} = \frac{{S}^{2} * Δ T * α}{P} * 100 \%$$

$${η}_{2} = ( T - {T}_{h} ) * \vert γ \vert$$

where Δη is the amount of generated power increased by an PV module of the present application η₁ is the amount of generated power increased by a thermoelectric module of the PV module of the present application; η₂ is the amount of generated power lost by a conventional PV module due to temperature; S is the area of the PV module; ΔT is solar cell temperature reduced by power generation of the thermoelectric module, generally 20° C.; α is conversion efficiency of the thermoelectric module; P is the power of the PV module; T is surface temperature of the PV module; Th is ambient temperature; and γ is a temperature coefficient of the PV module.

Therefore, a lower limit of the amount of generated power increased by the PV module of the present application is:

$$Δη = \frac{{( 2.3 \times 1.1 )}^{2} \times 20 \times 18 \%}{540} \times 100 \% + 35 \times \vert - 0.35 \% \vert = 16.52 \%$$

wherein the thermoelectric conversion efficiency and the temperature difference take intermediate values.

An upper limit of the amount of generated power increased by the PV module of the present application in winter is:

$$Δη = \frac{{( 2.3 \times 1.1 )}^{2} \times 20 \times 18 \%}{540} \times 100 \% + 25 \times \vert - 0.35 \% \vert = 13.02 \%$$

wherein the upper limit is when the temperature difference, an absolute value of the temperature coefficient and the thermoelectric conversion efficiency are maximum.

At present, power generation efficiency of thermoelectric materials is 16% to 20%. Using a PV module with a power of 540W and a size of 2.3*1.1m as an example, in combined with an PV module temperature coefficient (−0.35%/° C.), the PV module provided in the present application can increase the amount of generated power by 13.02% to 16.52% while reducing the temperature.

In summary, using the PV effect and the Seebeck effect, a low-temperature bifacial PV module of the present application is capable of not only PV power generation, but also temperature-difference power generation using waste heat, thus greatly improving the utilization rate of solar energy and power generation efficiency. The thermoelectric module layer reduces the temperature of the PV module by temperature-difference power generation, and the thermoelectric module layer has the characteristics of no noise, no abrasion, no leakage, good mobility, etc. in operation, and is not restricted by the site environment of a power station. It prevents hot spots generated due to high local temperature of the PV module, thereby saving diodes; and reduces the aging rate of the PV module, extends the service life of the PV module, and improves the safety performance of the PV module.

The above is only intended to illustrate technical ideas of the present application, and the scope of protection of the present application is not limited thereto. Any changes made on the basis of the technical solutions in accordance with the technical ideas proposed in the present application fall within the scope of protection of the claims of the present application.

1. A low-temperature bifacial photovoltaic module, comprising a backsheet of PV module, with a junction box being provided on one side of the backsheet of PV module and a thermoelectric module layer being provided on the other side of the backsheet of PV module, a cold end of the thermoelectric module layer being connected to the backsheet of PV module, a hot end of the thermoelectric module layer being connected to one side of the PV module, and a glass panel being provided on the other side of the PV module;
wherein the thermoelectric module layer comprises a plurality of p/n-type semiconductors, the plurality of p/n-type semiconductors being arranged in an array, to achieve direct conversion from thermal energy to electrical energy by utilizing a temperature difference between the p/n-type semiconductors and the PV module.

2. The low-temperature bifacial PV module according to claim 1, wherein one end of each of the p/n-type semiconductors is connected to the PV module through a base.

3. The low-temperature bifacial PV module according to claim 2, wherein a corresponding metal connection sheet is provided between each p/n-type semiconductor and the base.

4. The low-temperature bifacial PV module according to claim 1, wherein the plurality of p/n-type semiconductors are successively connected in series by a busbar to form the thermoelectric module layer, and positive and negative electrodes of the thermoelectric module layer are respectively connected to positive and negative electrodes of the junction box.

5. The low-temperature bifacial PV module according to claim 4, wherein the p/n-type semiconductors are connected to the backsheet of PV module through metal connection sheets.

6. The low-temperature bifacial PV module according to claim 1, wherein positive and negative electrodes of the PV module are respectively connected to positive and negative electrodes of the junction box.

7. The low-temperature bifacial PV module according to claim 6, wherein the assembly comprises a plurality of solar cells, the plurality of solar cells being connected in series or in parallel by means of a busbar.

8. The low-temperature bifacial PV module according to claim 1, wherein each of the p/n-type semiconductors is made of a nano-block system, an organic polymer material system or a carbon material system.

9. The low-temperature bifacial PV module according to claim 1, wherein a first EVA/POE layer is provided between the PV module and the glass panel, a second EVA/POE layer is provided between the thermoelectric module layer and the PV module, and a third EVA/POE layer is provided between the thermoelectric module layer and the backsheet of PV module.

10. The low-temperature bifacial PV module according to claim 1, wherein the glass panel, the PV module, the thermoelectric module layer and the backsheet of PV module are encapsulated by an aluminum frame.
